(19) United States
(12) Patent Application Publication
(10) Pub. No.: US 2012/0211609 A1
(43) Pub. Date: Aug. 23, 2012

(54) Cable Support and Methods of Supporting Cables

(76) Inventor: Zeljko Mandic, Hughesdale (AU)

(21) Appl. No.: 13/032,879

(22) Filed: Feb. 23, 2011

(51) Int. Cl. F16L 3/08; H01R 43/00; F16B 2/20; F16B 2/02; H05K 7/00; F16M 13/02

(52) U.S. Cl. 248/65; 248/309.1; 248/205.1; 248/231.81; 248/220.21; 248/226.11; 248/224.8; 248/225.11; 248/223.41; 29/825

(57) ABSTRACT

A cable support has a bed provided with a flat support section and a curved support section for supporting one or more cables on the cable support. The curved bed support section has a curvature which is greater than the curvature at which damage to a computer cable occurs when the cable is bent or folded around or over a small radius which can induce kinking or twisting of the cable. The curved support section provides a bed upon which the cable is supported at all times so that damage to the cable by bending too excessively is prevented. The support device is provided with fittings which are suitable for securely anchoring the support device to an open wire frame used to support the cables in cavities, such as ceiling cavities, roof spaces or the like without having to modify either the open wire frame or the support device thereby saving time and effort in installing computer cables.

### FIELD OF THE INVENTION

The present invention relates to supports for supporting electrical conductors when undergoing a change of direction and to methods of using such supports to support the electrical conductors when bending to change direction.

In one form, the present invention relates to a curved support for supporting electrical conductors when undergoing a change of direction so as to prevent the electrical conductors from bending excessively, such as for example, bending beyond a predetermined curvature in order to prevent damage to the electrical conductor, such as for example, due to kinking of the conductor.

In one form, the present invention relates to a curved cable support device for supporting flexible electrical cable when the cable transits from a usual storage position to an in use position by changing direction to enable the cable to be concealed or safely stored and be connected to electrical appliances, such as for example, computer hardware, and the like after undergoing the change of direction.

The present invention finds particular application as a curved computer cable support device for use with a wire tray support system for preventing computer cables from bending excessively when being directed towards an electrical appliance for connection thereto, such as for example, when being directed from the ceiling of a building to a work desk or workstation for connection to a computer located on the work desk or work station.

Although the present invention will be described with particular reference to one or more forms of a curved cable support device and method of supporting cables using the curved cable support device, it is to be noted that the scope of the present invention is not restricted to the described embodiment, but rather the scope of the present invention is more extensive so as to include other forms and arrangements of the support device and to the use of the various forms of the support devices in applications other than the application as specifically described.

### BACKBROUND OF THE INVENTION

Computers are becoming all invasive in both the home and the workplace. In many commercial environments, such as for example, offices, it is necessary to have banks of computers to enable working staff to complete their duties and/or to provide customer service and similar. The computers need to be connected not only to the power for operation, but also to each other and to computers in other locations as well as to other computer equipment. Electrical conductors in the form of cables are used to interconnect the computers and other equipment both within the one office (intra-office connection) and to other offices sometimes located some distance away (inter-office connection). This necessitates the use of many kilometers of cable within an office or other building which must be stored neatly and safely. Cables are either located in conduits, raceways or similar located along the floor, under floor, at the junction of the floor and walls, in the ceiling, roof cavity or the like generally in a horizontally oriented configuration as the cables extend from one location to another location. However, it is often necessary to direct the cables to workstations, work desks and other locations within a building. This necessitates bending the cable from the generally horizontal storage configurations, such as in a storage conduit or similar to the vertical or near vertical configuration to be aligned with the computer appliance or other equipment including accessories so that the cable can be connected to the appliance or the like. Often bending the cables from the horizontal to the near vertical causes damage to the cables, such as by kinking, twisting, inelastically deforming, knotting or similar as the cable is stretched or pulled to make the connection. In some instances, the cable is bent around an edge or corner resulting in damage to the cable.

With the increasing complexity of cables and also the increasing thickness and diameter or similar, the minimum radius through which the cables can be bent without causing damage becomes increasingly critical to prevent damage to the cables, particularly to prevent irreparable damage. As cables become capable of transferring increasing amounts of data, their installation requirements become more stringent requiring greater care, skill, experience and knowledge of the installers and installations, if the cables are to be installed correctly and to continue to work correctly. It is no longer sufficient to merely allow a modern complex cable, such as CAT5 or CAT6 cable, to bend uncontrollably when being installed and/or connected to computer equipment as the bend radius of the cable may be reduced to such an extent so as to cause damage to the cable, such as by bending beyond the minimum bend radius thereby resulting in breaking, crimping, crinkling, kinking, twisting, knotting or other damage to the cable which could result in loss of performance of the cable and/or computer system or be responsible for the complete computer system “going down” and not working. Cable faults are hard to diagnose and are often virtually impossible to access because of the location of the cable in cavities and the like within buildings.

While there have been previous attempts at controlling the curvature of cables when being bent, such previous attempts have not been entirely successful for one reason or other. One reason for the failure of previous attempts to control the bending of cables is that the fittings that were used provided little or no control over the bend radius or the fittings provided to control the minimum radius of bending were poorly designed and adapted for this purpose, such as for example, previously available fittings required excessive amounts of time and effort to fit to the remainder of the support system, particularly when being fitted to wire tray support systems often used to support cables in the ceiling cavity of an office building, or the like.

Another problem of currently available fittings, is that the underlying support structure needed to be cut or modified such as for example, by providing an enlarged hole, aperture, or the like in the body of the fitting through which the cable could pass. In some instances, it was necessary to cut some of the wire strands or wire rods forming the wire trays before such fittings could be fitted. Again, it is time consuming and requires effort, particularly in confined spaces, to physically modify the existing support structure by cutting individual wires and other parts of the tray before the control fittings could be attached.

Therefore, there is a need for an improved system of controlling the minimum bend radius of minimum bending of cables during installation of the cables for a computer network in a building so as to prevent damage to the cables.

Further, there is a need for a support device that can be attached to a wire support tray that does not require modification of the wire support tray in order for the support device to be attached to the tray.

Further, there is a need for a cable support device that is easier to attach to wire support trays, and a further need for a support device that can be easily and quickly secured in place.

Accordingly, it is one aim of the present invention to provide a support device which can be used to control the bend radius or radius of bending of a flexible cable to maintain the bend above a predetermined minimum amount.

It is another aim of the present invention to provide a method of installing a cable support structure and/or cable guiding system which does not require physical modification to the remaining support structure but allows a support device to be readily located in place by being fitted or attached directly to the existing support structure.

It is another aim of the present invention to provide a curved support for supporting a cable during a change of direction so as to prevent damage to the cable which support can be directly attached or fitted to the existing support structure in such a manner to prevent excessive bending of the cable.

It is another aim of the present invention to provide a method of supporting a flexible conductor when changing direction to prevent damage to the conductor by controlling the amount of bending of the conductor and/or controlling the bend radius.

It is to be noted that not all embodiments of the present invention will satisfy all aims of the invention. Some embodiments can satisfy one aim while other embodiments can satisfy another aim. Some embodiments may satisfy two or more aims.

### SUMMARY OF THE INVENTION

According to one aspect of the present invention, there is provided a support for an electrical conductor for preventing the electrical conductor bending at a radius less than a predetermined radius comprising a main portion for substantially supporting the electrical conductor when extending in a first direction and a substantially curved portion having a radius of curvature for supporting the electrical conductor through a change of direction to a second direction, said second direction being different to the first direction, wherein the radius of curvature of the substantially curved portion is at least as great as the predetermined radius of bending of the electrical conductor at which damage could occur so that when the electrical conductor changes from the first direction to the second direction when supported on the curved support, the curved portion of the electrical conductor prevents the electrical conductor from bending at a radius less than the predetermined radius of curvature thereby reducing and/or preventing damage to the electrical conductor.

According to another aspect of the present invention, there is provided a method of supporting an electrical conductor when changing direction to reduce and/or prevent damage to the electrical conductor by between a first direction and a second direction using a support member for preventing the electrical conductor bending at a radius less than a predetermined radius at which damage to the cable occurs comprising including the steps of attaching the support member to a support structure whereby a curved portion of the support member extends from the support structure, at least partially aligned along the change of direction of the cable between the first and second directions, locating the electrical conductor on the support member so that a part of the electrical conductor is aligned along the curved portion to the support member to extend in the first direction and a further part of the electrical conductor extends in a second direction wherein the curved part of the support member is arranged at a radius greater than the radius at which damage to the electrical conductor is likely to occur so that when the electrical conductor is received on the curved part of the support member, the electrical conductor bends at a radius corresponding to the curvature of the support member thereby preventing damage to the electrical conductor.

According to the present invention, there is provided a method of installing a flexible electrical conductor using a support member having a curved portion to support the electrical conductor through a change of direction from a first direction to a second direction comprising the steps of locating the electrical connector upon the support member so that the curved portion of the support member supports the conductor when undergoing a change from a first direction to a second direction, wherein the curvature of the curved portion supports the conductor at a curvature at least as great as the curvature at which damage to the conductor occurs by bending due to bending at a curvature less than the curvature at which damage occurs to the conductor by bending.

According to another aspect of the present invention, there is provided a support member for supporting an electrical conductor in use to prevent damage to the electrical conductor by bending at a radius less than a predetermined radius, said support member comprising a support bed having a first portion which is a substantially straight planar portion, and a second portion which is a substantially curved portion, wherein when the electrical conductor is located on the support bed, the electrical conductor undergoes a change of direction from the first direction corresponding to the flat bed to a second direction corresponding to the curved portion wherein the radius of curvature of the substantially curved portion is at least as great as the predetermined radius of bending of the electrical conductor of the electrical conductor such that when the electrical conductor changes direction by being supported by the curved portion, the radius of bending is greater than the radius at which damage to the electrical conductor occurs thereby preventing damage to the electrical conductor.

### BRIEF DESCRIPTION OF EMBODIMENTS

Typically the electrical conductor is a flexible electrical conductor, more typically in the form of a conduit, wire, cable, chord or the like. More typically, the conductor is an insulated conductor. More typically, the conductor is an insulated flexible wire, conduit, conductor, cable, chord or the like. More typically, the electrical conductor is a flexible metallic cable or similar able to be bent through a radius of curvature. In one form, the metallic conductor is made from copper, aluminium, silver, gold, or other suitable metal including combinations thereof and alloys and the like. Preferably, the conductor is made from copper or a copper containing material. Most preferably, the electrical conductor is a CAT 5, CAT 6, CAT 7 or the like, flexible computer cable of the type used in computer network systems.

In one form, a CAT5 cable is a Category 5 cable which is a twisted pair high signal integrity cable type in a single cable jacket that can be used in computer applications, such as for connecting computers together using Ethernet connectivity, or the like. The jacket can be made from any suitable material including polyethylene, polyvinyl chloride or the like.

Typically, the support structure to which the support device of the present invention is attached in use to control the bend radius of the computer cable is a support structure of the type that can be inserted into the ceiling cavity, floor cavity, wall cavity, roof space, crawl space or the like of a building for housing computer cables. In one form, the support structure is a wire tray support system, typically a wire cable tray system comprising a multitude of interconnected wire cable trays arranged with respect to each other to define one or more pathways for supporting cables in and on their respective upper surfaces, when extending through the roof cavity, ceiling cavity or the like.

Typically, the tray is an open framework tray preferably an open grid tray, comprising a multitude of longitudinal wire elements and multitude of transverse wire elements interconnected together, typically at right angles to each other, to form an open grid arrangement having square or rectangular openings or voids defined between the wire elements for supporting electrical cables thereon. A typical example of the tray has a 50 mm×100 mm grid pattern with 4, 5 or 6 mm diameter rods welded together in rows and columns to form the tray. However, trays having any size, shape, cross-section or the like can be used. The trays are available in a multitude of different widths, lengths and depths.

Preferably, the wire tray support structure is suspended from or otherwise secured to or in the ceiling of a building so that the cable is supported on the wire tray in a horizontal configuration when in the usual storage position and can extend more or less vertically downward from the tray after passing through or over the support device of the present invention for connection to a suitable electrical appliance, such as for example, a computer as part of an interconnected network.

Typically, the cable is to extend from a generally horizontal direction or horizontal plane when located within the ceiling cavity to change direction to a substantially vertical direction to extend downwardly from the ceiling to a workstation, desktop or the like.

Typically, attachment of the support device of the present invention does not require modification of the wire support tray, such as for example, it does not require cutting of part of the tray to allow the support device to be fitted to the tray, but rather the support device may be directly attached to the wire support tray, such as by fitting onto, clipping onto, snap locking onto, being insertable into or the like, the tray.

In one form, the support device has a bed for receiving the cables thereon. In one form, the bed includes a flat planar portion and a curved end portion. Typically, the curved end portion curves away from the planar portion, i.e. an outside curve, so that the cable remains lying on the curved portion and is supported on the curved portion as it bends downwardly from the horizontal position to the vertical position so as to be supported by the curved surface to adopt a bend radius greater than the radius at which damage can occur.

In one form, the support device is a cable waterfall or similar device or product having a straight flat bed and a curved end bed.

Typically, the radius of curvature of the curved end portion of the support member device is from about 20 mm to about 100 mm, preferably from about 20 mm to 80 mm, more preferably from about 30 mm to 70 mm and more preferably about 40 mm to 60 mm, and even more preferably about 50 mm to 60 mm and most preferably about 55 mm.

Typically, the curve of the curve portion can be a simple curve having a constant radius or can be a complex curve having a variable radius which changes over the length of the curved portion. In one form, the radius increases in a direction towards the free end of the curved portion. In one form, the radius decreases in the direction towards the free end of the curved section.

In one form, the curvature of the walls, wings or guide portion is the same as the curvature of the curved portion. In one form, the curvature of the walls, wings or guide portion is different to the curvature of the curved portion. In one form, the curvature of the wings, walls or guides is greater than the curvature of the bed of the curved portion. In one form, the curvature of the curved section of the bed is constant to form an arc of a circle whereas the curvature of the wing or wall portion is variable to form a tapering arc so that the height of the wing or wall portion increases in the direction towards the free end of the curved portion so that the more the cable bends, the more the cable is retained in the bed by the walls.

Typically, the support device of the present invention is provided with fittings enabling the support member to be securely connected to the wire tray. In one form the fittings allow the support device to be clipped to the wire tray. In one form, the support device can be clipped onto the wire tray at any location and/or in a variety of orientations such as parallel to or perpendicular to the lengthwise extending axis of the tray.

In one form, the support device may be attached to the top of the wire tray whereas in another form, the device may be attached underneath the tray while being oriented to support the cables.

In one form, the device may be attached longitudinally to the tray so that the lengthwise extending axis of the device is aligned along the lengthwise extending axis of the tray to which it is attached whereas in another form, the device may be attached transversely to the tray so that the lengthwise extending axis of the support device is aligned across the lengthwise extending axis of the tray, such as for example, by the support device being arranged at right angles to the tray to which the support device is attached. Other orientations or arrangements are possible.

Typically, the fittings or clips include tongues, tabs, bosses, fingers, arms, legs, stops, teeth, feet or other projections extending from one or more parts of the device. More typically, the projections are arranged singly or in pairs, preferably in groups of pairs, such as for example closely spaced apart pairs forming a clamp, spring clip or similar arrangement. Even more typically, the projections are more or less resiliently attached to the support device. In one form, the projections are biased to an at-rest or usual position but can be deflected or deformed to engage with the wire or rod of the tray. The biasing force keeps the projection in contact with the wire or rod. In some embodiments, the projections cooperatively interact with one another to secure the support device to the tray, such as for example, by forming jaws of a clamp, vice, spring clip or similar in which the jaws are arranged in opposed face to face relationship with each other. The jaws open to receive the wire and rod between the individual jaw elements and then close around the wire or rod when received between the jaw elements.

In one form, the support device is provided with apertures, holes, perforations, bores, gaps, spaces, voids, slots, open channels, or the like. Preferably, the projections and voids cooperatively interact with each other to allow the support device to be secured to the wire support tray.

In one form, the support device is provided with tabs, lugs, projections, tongues or the like, typically frangibly connected to the support device so that the tabs etc., can be readily removed from the support device, such as for example, by being broken away, snap removed, tearably deflected or the like. In one form, the tabs are removed to form a space, gap, groove, rebate, void, slot, channel, groove or similar for receiving therein part of the wire tray so that the support device spans two units of the wire tray thereby enabling the tray to be made in one size for fitting to the wire tray.

Typically, the support device is provided with wings, walls, sides, flanges, guides, partitions, or the like located along one or more sides to assist in directing and/or containing cables on the bed of the device between the walls, etc. and to assist in strengthening the device by providing strengthening ribs, struts, braces, flanges, reinforcement elements, gussets or the like. More typically, the wings are located on either side of the support device to provide a substantially U-shaped transverse profile or cross-section forming the bed upon which the cables are located between the two side walls. The walls can be of any suitable size, shape or profile and be of any suitable thickness. More typically, the walls are provided with gussets, braces, ribs, reinforcing elements or strengthening elements or the like, to confer greater strength, rigidity, integrity of the like on the support device.

In one form, the upstanding sides of the support device are inclined, tapered, skewed, directed outwardly or similar, typically outwardly inclined to each other at the distal edges so as to diverge from one another along their respective outer edges enabling groups of individual substantially identical support devices to be stacked one upon the other, preferably nestably stacked one upon the other so as to reduce their volume when in stacked relationship for ease of transport at a reduced cost for storage.

Typically, the cables are constrained within the support device by a suitable fastener such as for example, a flexible fastener which fits over the cable, such as for example a cable tie, Velcro® strip, strap, loop, belt or the like. Additionally, or alternatively, the cables can be located within the tray using a releasably securable fastener, typically threadably received in one or more slots or apertures provided in the surface of the support device.

In one case, the fastener is a strap or belt, preferably a strap provided with complementary Velcro™ fittings at either end for being retained in a continuous or endless loop to hold the cables within the bed formed at the lower surface of the support device. More typically, the support device is provided with one or more apertures for receiving one or more straps therethrough to retain the straps on the device so that the cables can be securely located and/or retained on the support device in use.

Typically, the change of direction is from a first direction which is horizontal or substantially horizontal direction to a second direction which is substantially vertical direction. However, any other change of direction can be accommodated by the support device of the present invention depending upon the orientation of the support device or cable waterfall when attached or mounted to the tray.

Typically, the support device is provided with projections, protruberances, extensions or the like. More typically, the projections are in the form of feet, stops, spacers or the like for use in securing the device in position, such as for example, in a selected location within the open grid of the framework of the support tray. The projections can be fixed or can be resiliently attached to the support device, particularly the stops or locating feet.

Typically, the support device is a one piece integral device or is made of two or more pieces that can be assembled together to form the device such as for example be assembled by clicking together or snap locking the pieces together. In one form, the support device is a kit or is assembled. If provided as a kit of disassembled parts, the device can be formed by assembling the parts together before use.

The support device may be of a single width corresponding to the width of a single rectangular aperture of the open framework grid or tray support system or may be of a double, triple or greater width corresponding to the width of two, three or more rectangular apertures of the open framework grid or tray support system. In one form, the support device may be adjustable in width or may be of a fixed width with adjustable sections to allow improved flexibility of fitting the support device to the wire tray.

In one form, two or more support devices can be located in side-by-side relationship to one another to accommodate many multiples of cables. In one form, the support device in the form of a cable waterfall is provided with connectors located along one or both longitudinal sides of the support device for allowing two or more support devices to be connected together in side by side relationship to one another to adjust the width of the support device.

### BRIEF DESCRIPTION OF THE DRAWINGS

Embodiments of support devices will now be described to illustrate forms or examples of the support device by way of non-limiting examples with reference to the accompanying drawings in which:

FIG. 1 is a top perspective view of one form of the support device of the present invention.

FIG. 2 is an underneath perspective view of the support device of FIG. 1.

FIG. 3 is a perspective view of the support device of FIGS. 1 and 2 in the process of being attached to the open framework of part of a wire support tray.

FIG. 4 is a top perspective view showing the support device located in situ on one form of the wire support tray.

FIG. 5 is an underneath perspective view showing the support device aligned between two adjacent longitudinal wore rods and clipped to adjacent transverse wire rods in a rectangular void of the support tray.

FIG. 6 is an underneath plan view of the support device of FIG. 5.

FIG. 7 is a top perspective view of a modified form of the support device of the present invention having a double width for spanning two adjacent openings of the tray.

FIG. 8 is an underneath view of the support device of FIG. 7.

FIG. 9 is an underneath view of the support device of FIGS. 7 and 8 attached to the wire support tray spanning two adjacent apertures.

FIG. 10 is an underneath plan view of the support tray of FIGS. 7 and 8 attached to the wire support tray.

FIG. 11 is a schematic top perspective view of another form of the support device shown in isolation having a removable tab in which the tab is shown attached to the support device.

FIG. 12 is a schematic top perspective view of the form of the device of FIG. 11 from which the removable tab has been removed forming an elongate slot shown in situ fitted to one form of the wire tray with a wire rod received through the elongate slot.

### DETAILED DESCRIPTION OF THE INVENTION

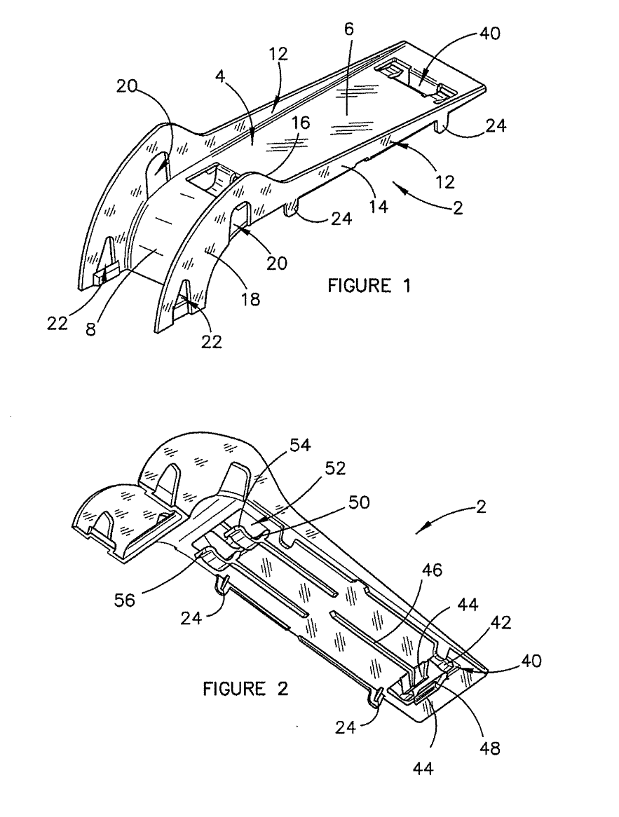

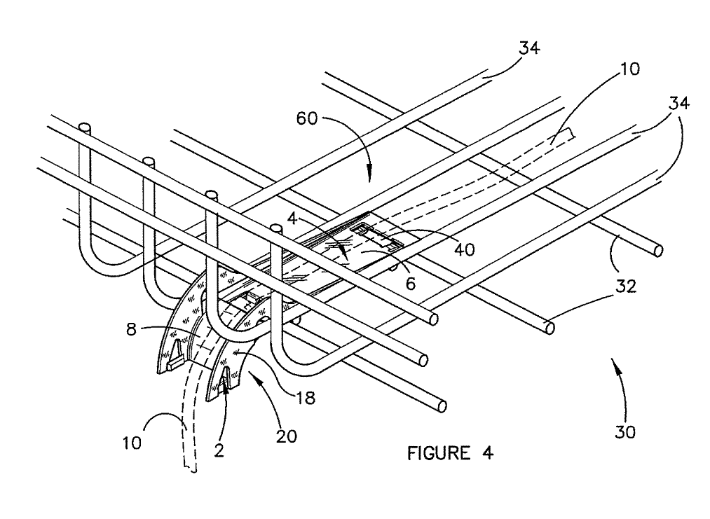

One form of the curved support device of the present invention will now be described with particular reference to FIGS. 1 to 6.

This form of the support device, generally denoted as 2 has a main support region in the form of a bed 4 having a generally planar straight bed portion 6 and a generally curved end portion 8 integrally formed as a single device. Straight portion 6 and curved portion 8 form the bed of the support device 2 for supporting one or more cables 10 in use. A generally perpendicular upstanding wall 12 is located on either side of the bed of the device for containing cables 10 within the confines of the support device 2. In one form, wall 12 has a first portion 14 which tapers from the inboard end of the straight portion of the wall towards the distal end of the flat bed portion 6, and a generally upswept wall portion 16 located intermediate the straight tapering portion 14 and a generally curved wall portion 18 aligned to curve more or less correspondingly, with the curve of end curved bed 8 at the curved end of device 2. An aperture 20 is provided in the proximal end of curved portion 18 of wall 12 for receiving therethrough a suitable fastener to retain cables 10 on bed 4 of support device 2 in use. In one form, the fastener is a releasably securable fastener, such as for example, a strap or cable tie or similar (not shown), capable of being threaded through the two aligned apertures 20 on either side of device 2 and looped over the top of the curved wall 18 to restrain cables 10 on bed 4 of the device thereby preventing the cables from being dislodged from device 2. The straps are preferably provided with Velcro™ pads or similar at or towards either end for fastening the ends of the strap together to retain cables 10. It is to be noted that apertures 20 can have any suitable shape, size or profile to assist in retaining the cables on the bed. The strap need not contact cables 10 but may pass over the cables to keep them contained in the support device by preventing the cables from raising out of the bed of support device 2.

A pair of generally triangular shaped apertures 22 are provided at the downwardly depending end of the curved portion 18 of each side wall 12 for receiving therethrough flexible fasteners (not shown) to assist in retaining cables 10 on device 2 either as an alternative to or in addition to the strap received through aligned apertures 20.

A pair of spaced apart stops 24, are provided on each side of device 2 as a pair of downwardly depending extensions or feet of wall 12. Stops 24 are provided to assist accurate location of device 2 on a suitable wire support tray and to assist in maintaining the support device securely onto the wire tray support in use as will be described in more detail.

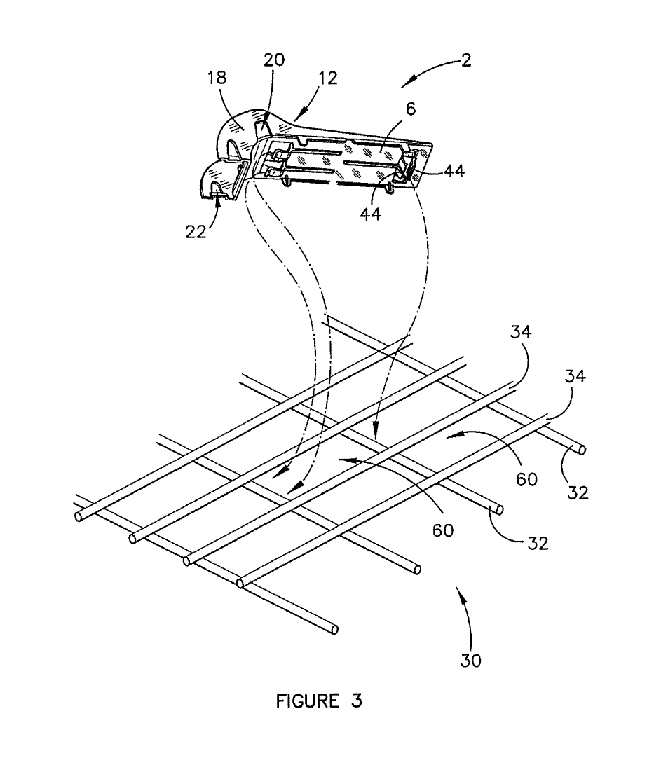

Device 2 is provided with fittings for connecting or attaching support device 2 to a wire tray, generally denoted as 30, particularly to the longitudinal extending members 34 and/or the transversely extending members 32 of the wire tray 30. In one form, the fittings are clips, clamps or similar snap lock fittings having a pair of opposed arms, fingers or jaws for quickly snap-lockingly attaching device 2 to wire tray 30 as shown more particularly in FIGS. 3 to 6.

One form of the snap fittings will now be described.

In one form, there is a generally rectangular aperture 40 formed in the distal end of the flat portion 6 forming part of the bed of device 2. A first lengthwise extending tongue 42 extends from the inboard edge of the rectangular aperture 40 for most of the width of the rectangular aperture 40. Tongue 42 is of a generally bent shape having a transversely extending groove located part way along the length of the tongue in the upper surface and a corresponding crest located in the lower surface for engaging against one of the transverse wire members 32, forming tray 30. Another identical lengthwise extending tongue 42 is located on the other side of the rectangular aperture 40 to form a pair of tongues 42 for engaging the top surface of transverse wire strand or wire rod 32, of the support tray.

A pair of downwardly depending tabs 44 are provided intermediate the two lengthwise extending tongues 42 in opposed face to face relationship to each other in which one of the tabs 44 extends from the outboard edge of the rectangular aperture 40 and another of the tabs 44 extends from the inboard edge of the rectangular aperture 40. A longitudinally extending strengthening rib 46 is provided on the underside of the flat bed and extends onto the inboard tab 44 to provide strength and resiliency for the fitting.

Each tab 44 is provided with a transversely extending flange 48 or ridge located at or towards the distal end for engaging wire strand 32 of the wire support tray.

A first pair of the downwardly depending stops 24, one on either side of device 2, extend from the under surface of flat bed 6 to bear against one of longitudinal wire strands 34 of tray 30 in use to assist in positioning device 2 with respect to tray 30.

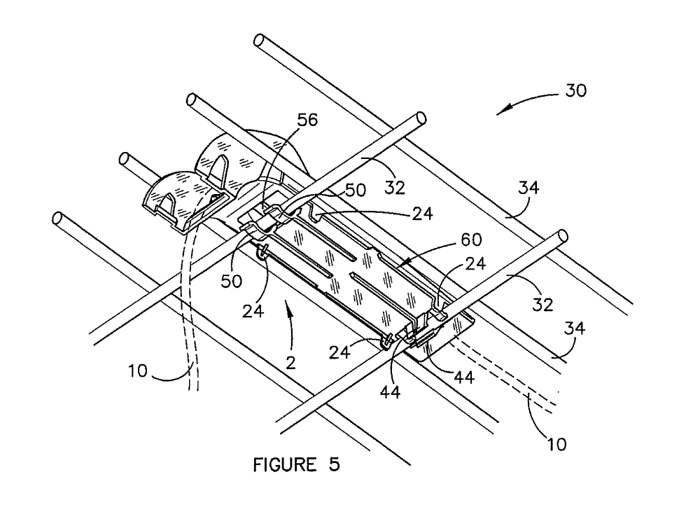

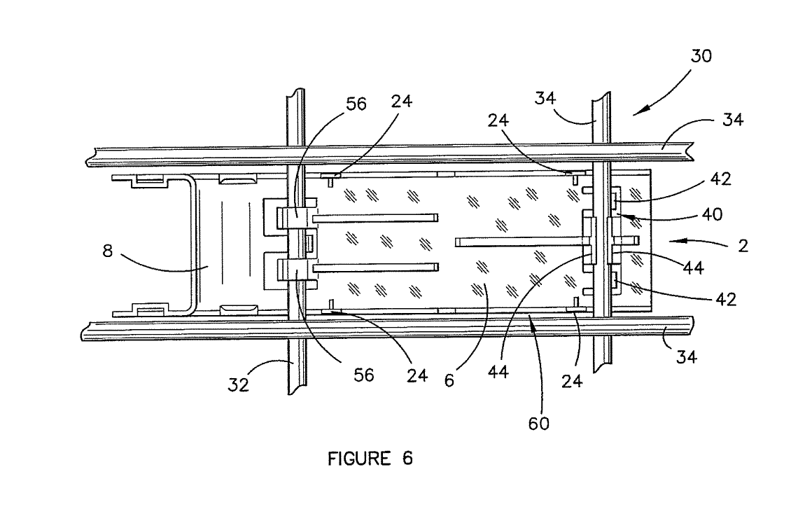

Therefore, this end of support device 2 may be attached to one transverse strand 32 of the wire tray by having strand 32 being received between the two downwardly depending tabs 44 in opposed face to face relationship forming the opposite sides, arms, fingers, jaws and the like of a clamp, to clamp the sides of the wire strand between flanges 48 at the ends of tabs 44, and on the lower side of the wire, the two lengthwise extending tongues 42 bearing against the upper side of the strand 32 of wire as shown more particularly in FIGS. 5 and 6 thus securely attaching support device 2 to two adjacent wire rods 34 as shown more particularly in FIG. 5.

Device 2 is also provided with suitable fittings at or towards the curved end for attaching device 2 to wire tray 30. The fittings at the curved end will now be described.

A pair of generally arcuate hooks 50 extend from the inboard edge of a rectangular aperture 52 provided at or towards the curved end of device 2. Hooks 50 are provided with inclined flanges or tips 54 located at their respective distal ends defining an opening to engage another converse wire strand 32 between the inner or upper surfaces of the hooks to assist location of device 2 when received in and/or through the rectangular opening defined between two adjacent longitudinal wires or rods 34 and two adjacent transverse wires or rods 32. A resilient finger 56 extends from the outboard edge of rectangular aperture 52 towards the other side of the rectangular aperture 52 and is located intermediate the position of two hooks 50. Resilient finger 56 rests upon the top surface of wire strand 32 when device 2 is clipped into place on wire tray 30.

A second pair of downwardly depending stops 24, are provided as extensions to either side wall 12 in the region near the upswept part 16 of the wall to assist in locating the device on to wire tray 30.

Use of the support device 2 of the present invention will now be described.

When it is desired that a computer cable 10 be arranged to extend from say, the ceiling to a workstation or work desk, it is necessary to insert a support device 2 on the wire tray 30 above the area in which computer cable 10 is to downwardly depend. When the exact location of the support device is determined, curved support device 2 of the present invention is selected and the curved end 8 fitted to one wire 32 between two adjacent wires 34 of support tray 30 by engaging two hooks 50 underneath wire 32 with the resilient finger 56 resting upon the top of wire 32. The other end of support device 2 may be clipped to an adjacent strand 32 of wire by pushing down on the flat end of device 2 so that the wire 32 is squeezed between the two downwardly depending tabs 44 and held between tabs 44 by the flanges 48 engaging against the underside of wire strand 32 and tongues 42 engaging the upper side of wire strand 32 to clamp the wire between tabs 44 and tongues 42 as shown more particularly in FIG. 5. The four downwardly depending stops 24 are received in rectangular space 60 defined by the four wires 32, 34 and engage against the wires at the corners of aperture 52 defined by the open grid to prevent lateral movement of support device 2 and/or to prevent back and forth movement of the device by stoppingly engaging against wires 34 thus preventing movement of the device 2. Thus, support device 2 is prevented from moving in any direction and accordingly is securely held in place.

When the support device 2 is firmly attached to the wire support tray 30 at the desired location as shown in FIG. 5, cable 10 can be placed on the flat bed 6 of the support device 2 and curved around the curve portion 8 so as to extend downwardly from the device 2 and from the ceiling. As the curvature of the curved portion 8 is greater than the minimum radius of bending of the cable 10 at which damage to the cable can occur, or is likely to occur, the cable is prevented from bending at a radius smaller or tighter than the radius of curvature of the curved portion 8 and thus is prevented from being damaged even when the cable is pulled or otherwise manipulated since the curved portion 8 of the support device 2 determines the minimum bend radius through which the cable 10 can bend when changing direction from the horizontal orientation or configuration within the ceiling to the vertical orientation or configuration when extending from the ceiling for connection to the computer equipment located below or beneath the ceiling.

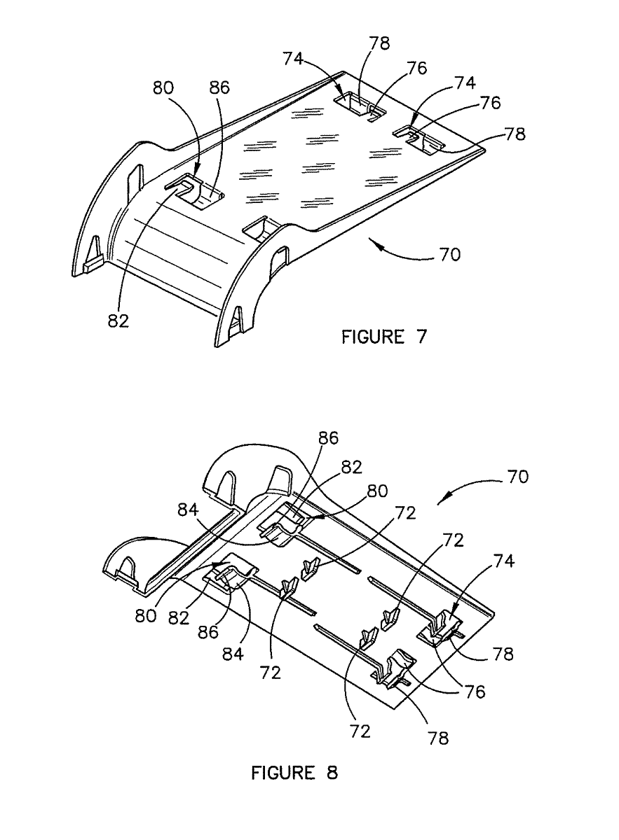

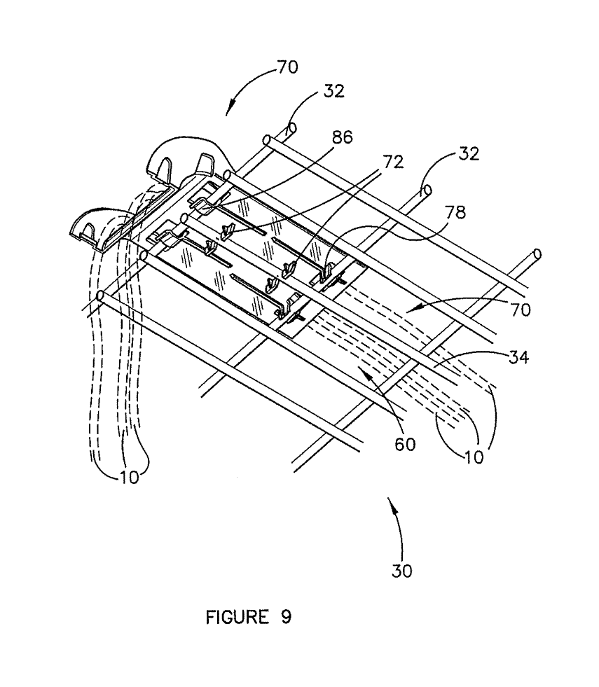

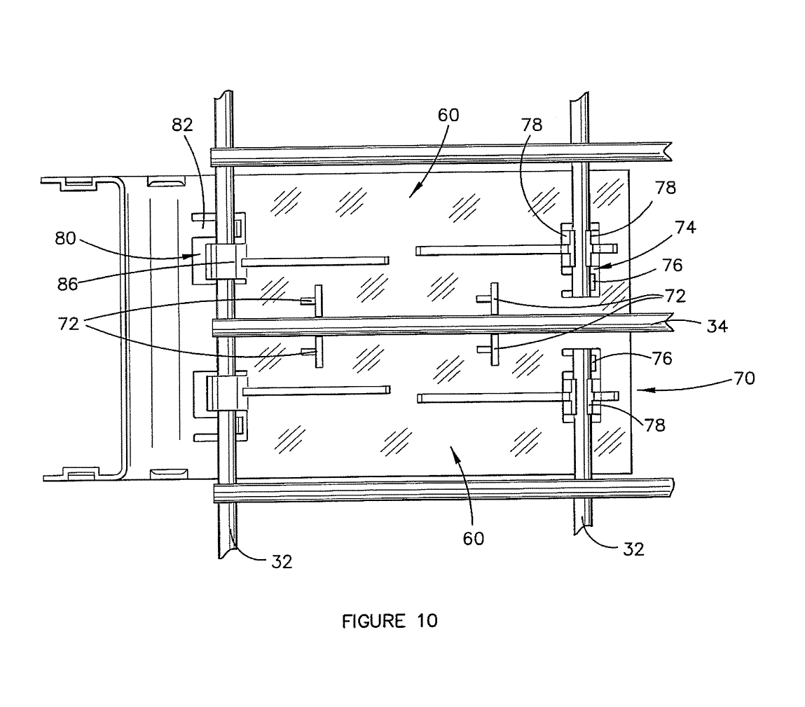

Any number of cables 10 can be located on the support device 2 of the present invention. However, if a large number of individual cables need to be supported, a modified form of the support device of FIGS. 1 to 6 can be used. This modified form is shown in FIGS. 7 to 10 which is a double width support device. Essentially, this form of the device is similar to the form of the device shown in FIGS. 1 to 6 except that it is provided with a bed which is about as twice as wide as the bed of support device 2 shown in FIGS. 1 to 6 and can be clipped into two adjacent rectangular spaces 60 in side-by-side relationship to each other to mount the support device to the tray as shown in FIGS. 9 and 10.

In this modified form of the support device, generally denoted as 70, there is provided a multitude of downwardly depending stops located inboard of the device 70. Instead of the stops being located as extensions of the side walls as in support device 2, in this form of the support device 70, the four stops 72 are arranged as two spaced apart pairs of stops in which the two stops forming one pair are spaced apart from each other in transverse spaced apart relationship to each other and the two stops forming the other pair are spaced apart from each other in transverse spaced apart relationship to each other and both pairs are spaced apart from each other in longitudinal spaced apart relationship to each other as shown more particularly in FIG. 8. The four stops 72 are spaced apart to straddle a longitudinal wire strand or rod 34 received between the two stops forming the pair as shown more particularly in FIGS. 9 and 10. In addition, the arrangement of the tabs 44 and tongues 42 at the flat end of the device are different to the arrangement of support device 2 in that there are two rectangular apertures 74 located in transverse side-by-side spaced apart relationship at the flat end in which each rectangular aperture is provided with a generally longitudinally extending resilient tongue 76 extending generally in a plane parallel to the plane of the flat bed of the support device and a pair of downwardly depending opposed face-to-face tabs 78 extending substantially perpendicularly to the plane of the flat bed of the support device as shown more particularly in FIG. 8 at or towards the flat end of device 70.

Similarly, the fitting at the curved end of the device 70 is different to the fittings at the curved end of device 2 in that there are two side-by-side transversely spaced apart rectangular apertures 80 in which each aperture 80 is provided with an inboardly extending resilient finger 82 arranged to extend in a plane substantially parallel to the flat bed of the support device, and a downwardly depending and inboardly extending hook 84 extending into aperture 80 in the opposite direction to resilient finger 82. Hook 84 is provided with a distal inclined flange 86 defining an opening or entrance to an opening for receiving therein or therethrough transverse wire rod 32.

The spacing apart of one side of the fittings 82 from the fittings 86 on the other side allows the fittings from one side to engage with a strand 32 of wire in one aperture formed in the wire open grid network of the wire tray and the fittings to engage the same strand in the adjacent aperture of the open framework of the wire tray as shown in FIGS. 9 and 10.

In another form of a modified support device, there is a centrally located lengthwise extending groove or trough for being received over the centrally located strand of wire enabling the device to be clipped onto the tray with the centrally located strand being received within the centrally located groove so that the support device can be securely attached to the wire tray.

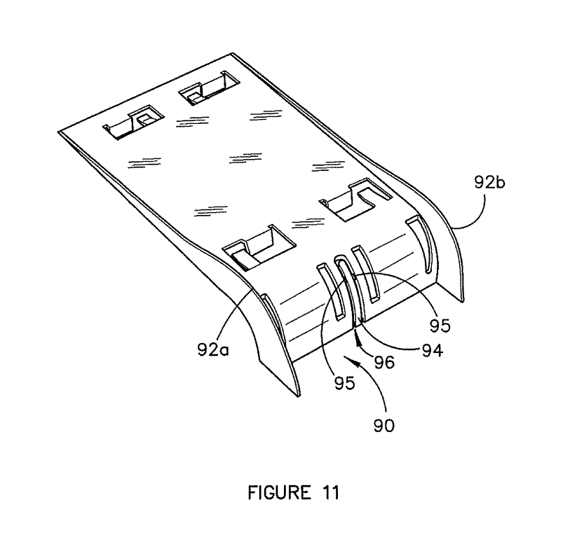

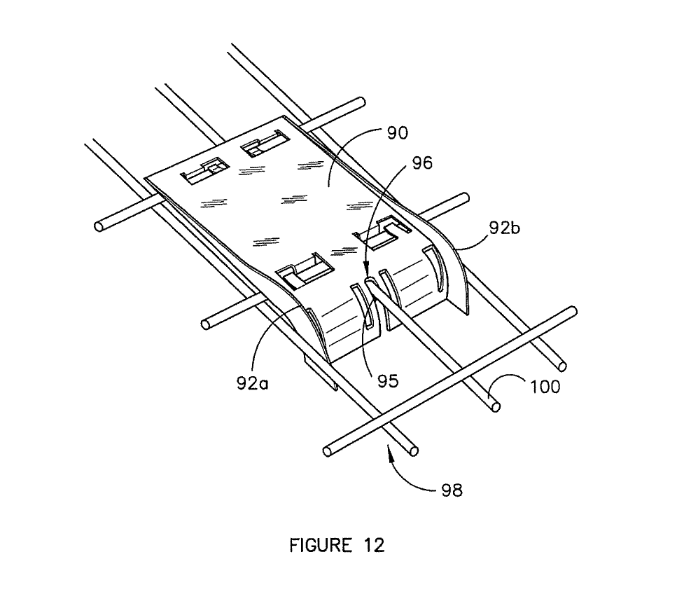

Another modification of the support device is shown in FIGS. 11 and 12. In this form, generally denoted as 90 in FIGS. 11 and 12, there are two opposing diverging upstanding side walls 92a, 92b located on either side of support device 90. Walls 92a, 92b are tapered outwardly from their proximal ends in the direction to their respective distal ends to assist nesting when two or more support devices are stacked one upon the other. In one form as shown in FIG. 11, there is a removable tab 94 located intermediate side walls 92a, 92b at the front curved part of support 90. Tab 94 at one end is frangibly connected to the support 90 by nibs 95 on either side of tab 94, so that if required, tab 94 can be readily removed from support 90 by bending tab 94 until the frangible connection, i.e. nibs 95 are severed allowing tab 94 to be removed entirely thereby forming groove 96 as shown more particularly in FIG. 12. After removing tab 94 from support device 90, when fitting device 90 to wire tray 98, one of the lengthwise extending wire rods 100 can be received through groove 96 to allow support 90 to be attached to tray 98. This form of device 90 can thus span two side by side sections of tray 98 therefore obviating the need to have different size support devices for different situations by having to have only one size which can be customized for installing in any situation by simply breaking nibs 95 and removing tab 94 to form slot 96 as required. It is to be noted that the support device can have any number of removable tabs at any suitable or convenient locations and in any form or arrangement to assist in flexibly mounting device 90 to wire tray 98 as the particular situation demands.

It is to be noted that any form of frangible connection is possible such as for example, having a single breakaway nib, or two or more breakaway nibs, optionally arranged in pairs or the like located at spaced apart locations to one another.

Returning to side walls 92a, 92b of support device 90, the curvature of the upper edge of each wall is of a variable radius so that the upper edges taper from having a relatively narrow height at the inboard end of device 90 and a greater height at or towards the distal or free end of the walls. The variable radius or curvature as shown in FIGS. 11 and 12 is to provide increased retention of cables as the cables curve downward on the bed of device 90 so as to stay in contact with the curved part of support device 90.

Another modification of the support device is to have one or more strengthening ribs located on the reverse side of support device 90 such as for example, four such ribs, extending in spaced apart substantially parallel relationship to one another extending from the curved forward edge of device 90 in a direction towards the rear of the device to terminate prior to the location of protrusions for clipping device 90 onto wire tray 98. It is to be noted that any number of ribs, at any location, and of any configuration may be present to strengthen the support device as required.

Other modifications of the device of the present invention include that manufacturing one or more of the various forms of the support device as an integral product such as by molding the device as a one piece molding or the support device may be made as a kit in which the components can be assembled together.

The support device of the present invention can be made of any suitable material including polyethylene, polypropylene, polyvinylchloride or any other suitable materials including plastics materials and/or metal materials or combinations thereof.

The support device may take any size, shape, form or profile depending upon circumstances.

The curvature of the curved end can adopt any suitable profile or radius of curvature from about 20 mm to 100 mm.

### ADVANTAGES OF THE PRESENT INVENTION

The advantages of the present invention include the following.

The support device of the present invention can be clipped or snaplockingly fitted to a wire tray without having to modify the wire tray, such as for example by removing or cutting a strand or a part of a strand from the wire tray.

The curved part of the device prevents the cable from bending through a radius less than the radius of the curved part thereby preventing damage to the cable by bending through too small or tight a radius.

It is to be understood that, if any prior art publication is referred to herein, such reference does not constitute an admission that the publication forms a part of the common general knowledge in the art, in Australia or any other country.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

1. A support for an electrical conductor for preventing the electrical conductor bending at a radius less than a predetermined radius comprising a main portion for substantially supporting the electrical conductor when extending in a first direction and a substantially curved portion having a radius of curvature for supporting the electrical conductor through a change of direction to a second direction, said second direction being different to the first direction, wherein the radius of curvature of the substantially curved portion is at least as great as the predetermined radius of bending of the electrical conductor at which damage could occur so that when the electrical conductor changes from the first direction to the second direction when supported on the curved support, the curved portion of the electrical conductor prevents the electrical conductor from bending at a radius less than the predetermined radius of curvature thereby reducing and/or preventing damage to the electrical conductor.

2. A support device according to claim 1 in which the electrical conductor is a cable including a category 5, category 6 or category 7 cable or the like of the type that is used for connecting individual items of a computer network or array.

3. A support device according to claim 1 in which the support device is connectable to a second support device in the form of a wire tray support system comprising a multitude of interconnected wire cable trays arranged with respect to each other to form at least one pathway for supporting cables on their respective upper surfaces.

4. A support device according to claim 3 in which the wire support tray is an open framework comprising a multitude on longitudinally extending wire or rod elements and a multitude of transverse wire or rod elements interconnected together substantially perpendicular to one another to form an open grid arrangement having a multitude of rectangular spaces into which the support device is received.

5. A support device according to claim 1 in which the first direction is a substantially horizontal direction and the second direction is substantially vertical so that the cable extends from the generally horizontal direction or horizontal configuration or horizontal orientation when located within a tray situated in a cavity to change direction to the substantially vertical direction, configuration or orientation so as to extend downwardly from the ceiling to the item being connected by the cable.

6. A support device according to claim 5 in which the curved portion is an end portion and the main portion is a planar portion such that the end portion curves away from the planar portion and the curved portion is in a form of an outside curve for supporting the cable as the cable transits from the substantially horizontal position or orientation to the substantially vertical position so that the cable is supported on the curved portion as it bends downwardly from the horizontal position to the vertical position.

7. A support device according to claim 6 in which the radius of curvature of the curved end portion of the support device is from about 20 mm to about 100 mm, preferably from about 20 mm to about 80 mm, more preferably from about 25 mm to 70 mm and most preferably about 30 mm.

8. A support device according to claim 1 in which the device is provided with a fitting enabling the support device to be clipped to the wire tray so that the support device can be oriented in one or more orientations with respect to the wire tray to provide support for the cable as the cable changes direction.

9. A support device according to claim 3 in which the support device is attached to the upper surface of the wire tray or is attached to the lower surface of the wire tray or is attached to both the upper and lower surface of the wire tray.

10. A support device according to claim 3 in which the support device is attached longitudinally to the tray so that the lengthwise extending axis of the support device is aligned along the lengthwise extending axis of the tray or the support device is attached transversely to the tray so that the lengthwise extending axis of the support device is aligned transverse to the lengthwise extending axis of the tray.

11. A support device according to claim 3 in which the device is provided with fittings for attaching the support device to the tray in which the fittings include clips, tongues, tabs, bosses, fingers, arms, legs, stops, teeth, feet, jaws, projections and wherein the fittings are fixedly attached to the support device or are resiliently attached so as to be elastically deformable to assist in mounting the support device to the tray.

12. A support device according to claim 1 in which the fittings are arranged in the form of projections either singly or in pairs or in one or more groups of pairs including one or more pairs of closely spaced apart elements forming a clamp or similar arrangement for engaging the wire tray on either side of the wire or rod to which the support device is attached so that the wire or rod is received between the two elements of the pair to mount the support device to the tray.

13. A support device according to claim 11 in which the fittings for attaching the support device to the tray are jaws of a clamp, vice, spring clip or the like in which the elements forming the jaws are arranged in opposed face to face relationship with each other to cooperatively engage with the wire tray.

14. A support device according to claim 11 in which the fittings in the form of projections cooperatively interact with apertures, holes, perforations, bores, gaps, spaces, voids, slots, open channels, grooves or the like to allow the support device to be securely mounted to the tray.

15. A support device according to claim 1 in which the support device is provided with projections in the form of tabs, lugs, projections, tongues, bosses or similar which are frangibly connected to the support device for ready removal from the support device to allow the support device to be mounted to the tray.

16. A support device according to claim 15 in which when the frangible projection is removed from the support device, a space, gap, groove, rebate, void, cavity, slot or similar is produced for receiving therein or therethrough part of the wire tray to which the support device is mounted.

17. A support device according to claim 1 in which the support device is provided with wall portions for containing the cable when on the support device wherein the wall portions are in the form of wings, walls, sides, flanges, partitions, guides.

18. A support device according to claim 17 in which the wall portions are provided with strengthening elements so as to strengthen the wall portions or support device wherein the strengthening elements are in the form of strengthening ribs, struts, braces, reinforcing elements, gussets or the like.

19. A support device according to claim 17 in which there are one or more wall portions located on the support device including a wall portion located on one side of the support device, wall portions located on either side of the support device to form a substantially U-shaped profile of the support device including the two side wings and flat bed of the support device.

20. A support device according to claim 17 in which the wall portions are inclined, tapered, skewed, angulated or the like, typically outwardly inclined to the flat bed so as to form an opening having diverging walls along the respective outer edges of the support device enabling a multiplicity of support devices to be stacked in nested relationship one upon the other.

21. A support device according to claim 1 in which the support device further includes a fastener for maintaining the cable within the support device wherein the fastener is in the form of a cable tie, Velcro™ strip, strap, loop or other flexible fastener for engaging with the cable to secure the cable in the bed of the support device.

22. A support device according to claim 1 in which the support device further includes projections, protruberances, bosses or similar in the form of feet, stops, spacers, or the like for use in securing the device in position with respect to the wire tray by the projections contacting a pair of wires or rods in spaced apart parallel relationship on either side of the support device.

23. A support device according to claim 1 in which the support device is a one piece integral unit or is made from two or more separate pieces that can be assembled together to form the support device.

24. A support device according to claim 1 in which the support device is a single width support device corresponding to the width of a single opening or void of the open framework grid of the tray support system or is a double, triple or has a greater width corresponding to the width of two, three or more apertures of the open framework grid or tray support system for supporting a multitude of individual cables.

25. A support device according to claim 1 in which the support device is in the form of a cable waterfall or similar accessory for supporting a cable.

26. A support member for supporting an electrical conductor in use to prevent damage to the electrical conductor by bending at a radius less than a predetermined radius, said support member comprising a support bed having a first portion which is a substantially straight planar portion, and a second portion which is a substantially curved portion, wherein when the electrical conductor is located on the support bed, the electrical conductor undergoes a change of direction from the first direction corresponding to the flat bed to a second direction corresponding to the curved portion wherein the radius of curvature of the substantially curved portion is at least as great as the predetermined radius of bending of the electrical conductor of the electrical conductor such that when the electrical conductor changes direction by being supported by the curved portion, the radius of bending is greater than the radius at which damage to the electrical conductor occurs thereby preventing damage to the electrical conductor.

27. A method of supporting an electrical conductor when changing direction to reduce and/or prevent damage to the electrical conductor by between a first direction and a second direction using a support member for preventing the electrical conductor bending at a radius less than a predetermined radius at which damage to the cable occurs comprising including the steps of attaching the support member to a support structure whereby a curved portion of the support member extends from the support structure, at least partially aligned along the change of direction of the cable between the first and second directions, locating the electrical conductor on the support member so that a part of the electrical conductor is aligned along the curved portion to the support member to extend in the first direction and a further part of the electrical conductor extends in a second direction wherein the curved part of the support member is arranged at a radius greater than the radius at which damage to the electrical conductor is likely to occur so that when the electrical conductor is received on the curved part of the support member, the electrical conductor bends at a radius corresponding to the curvature of the support member thereby preventing damage to the electrical conductor.
